(19) United States
(12) Patent Application Publication
(10) Pub. No.: US 2019/0322899 A1
(43) Pub. Date: Oct. 24, 2019

(54) CERIUM OXIDE ABRASIVE GRAINS

(71) Applicant: Kao Corporation, Tokyo (JP)

(72) Inventors: Koji KINUTA, Wakayama (JP); Shin OI, Wakayama (JP)

(73) Assignee: Kao Corporation, Tokyo (JP)

(21) Appl. No.: 16/475,036

(22) PCT Filed: Dec. 26, 2017
(86) PCT No.: PCT/JP2017/046533

§ 371 Date: Jun. 28, 2019

(30) Foreign Application Priority Data
Dec. 28, 2016 (JP) 2016-256308

(51) Int. Cl. C09G 1/02; C01F 17/00; C09K 3/14; B24B 37/04; H01L 21/3105

(52) U.S. Cl. CPC C09G 1/02; C01F 17/0043; C09K 3/1409; C01P 2004/03; H01L 21/31055; C01P 2004/64; C01P 2004/62; B24B 37/044

(57) ABSTRACT

In one aspect, the present disclosure provides cerium oxide abrasive grains that can improve the polishing rate.

One aspect of the present disclosure relates to cerium oxide abrasive grains for use in an abrasive, in which an amount of {100} faces exposed on a surface of each of the cerium oxide abrasive grains is at least 30%.

### TECHNICAL FIELD

The present disclosure relates to cerium oxide abrasive grains, a polishing liquid composition, and a semiconductor substrate production method, polishing method, and semiconductor device production method using the same.

### BACKGROUND ART

A chemical mechanical polishing (CMP) technique is a technique for planarizing a processing surface of a substrate to be polished by, in the state where the surface of the substrate is in contact with a polishing pad, relatively moving the substrate to be polished and the polishing pad while supplying a polishing liquid to the contact portion, thereby mechanically removing irregularities on the surface of the substrate while causing a chemical reaction.

The performance of the CMP technique is determined depending on the conditions of the CMP process, the type of polishing liquid, the type of polishing pad, and the like. Out of these factors, in particular, the polishing liquid is the factor that most significantly affects the performance of the CMP process. Silica (SiO₂) and ceria (CeO₂) are widely used as polishing particles contained in the polishing liquid.

Nowadays, in the process of producing semiconductor elements, this CMP technique is essential at the time of, e.g., planarizing an interlayer insulating film, forming a shallow trench element isolation structure (hereinafter also referred to as “element isolation structure”), and forming a plug and embedded metal wiring. In recent years, owing to dramatic improvements in terms of multilayering and definition of semiconductor elements, there is growing demand for further improvement in the yield and the throughput (production output) of the semiconductor elements. Under these circumstances, also for the CMP process, there is also a growing need for polishing that can be performed at a higher polishing rate without causing polishing flaws. For example, in the step of forming a shallow trench element isolation structure, there is demand for not only a higher polishing rate but also an improvement in polishing selectivity for a polishing stopper film (e.g., silicon nitride film) against a film to be polished (e.g., silicon oxide film) (in other words, selectivity in polishing such that the polishing stopper film is less susceptible to polishing than the film to be polished).

In particular, in technical fields relating to memories, which are used for general purposes, improvement in the throughput is an important issue, and in order to improve the throughput, abrasives are also being improved upon. For example, when ceria is used for polishing particles, a commonly known method to improve the polishing rate of a film to be polished (silicon oxide film) is to increase the particle size of the polishing particles. However, an increase in the particle size leads to an increase in polishing flaws, and this may result in reduced quality and reduction in yield.

To address this issue, for example, Patent Document 1 discloses a polishing liquid for CMP, which contains an inorganic abrasive composed of cerium oxide (ceria) or the like, a conductivity adjuster, and a dispersant, and has a conductivity from 8 to 1000 mS/m and a pH from 3.0 to 7.0.

Patent Document 2 discloses, as a polishing liquid composition for use in polishing of silicon oxide films, an aqueous polishing liquid composition that contains: (A) polishing particles containing ceria; (B) at least one water-soluble or water-dispersible polymer selected from linear and branched alkylene oxide homopolymers and copolymers; and (C) an anionic phosphate dispersant.

Patent Document 3 discloses a conditioner for a polishing pad for CMP polishing of metal films, including a base metal and a monolayer of super abrasive grains bound to a surface of the base metal with a binder. The super abrasive grains contain at least 40 wt % of hexaoctahedral super abrasive grains whose crystal faces are composed of both {100} and {111} faces.

### CITATION LIST

### Patent Documents

Patent Document 1: JP 2009-218558A
Patent Document 2: JP 2013-540849A
Patent Document 3 JP 2009-136926A

### DISCLOSURE OF INVENTION

### Problem to be Solved by the Invention

In recent years, in technical fields relating to semiconductors, the scale of integration is increasing, and further complication and miniaturization of wiring are required. This has led to growing demand for realization of polishing of silicon oxide films at a higher polishing rate.

The present disclosure provides cerium oxide abrasive grains that can improve the polishing rate, and a polishing liquid composition, semiconductor substrate production method, polishing method, and semiconductor device production method using the same.

### Means for Solving the Problem

The present disclosure relates to cerium oxide abrasive grains for use in an abrasive, wherein an amount of {100} faces exposed on a surface of each of the cerium oxide abrasive grains is at least 30%.

The present disclosure relates to a polishing liquid composition containing: the cerium oxide abrasive grains according to the present disclosure; and an aqueous medium.

The present disclosure relates to a method for producing a semiconductor substrate, including the step of polishing a substrate to be polished using the polishing liquid composition according to the present disclosure.

The present disclosure relates to a method for polishing a substrate, including the step of polishing a substrate to be polished using the polishing liquid composition according to the present disclosure.

The present disclosure relates to a method for producing a semiconductor device, including the step of: polishing a substrate to be polished using the polishing liquid composition according to the present disclosure.

### Effects of the Invention

The present disclosure can exhibit an effect that cerium oxide abrasive grains that can improve the polishing rate can be provided.

### BRIEF DESCRIPTION OF DRAWINGS

FIG. 1 shows an example of a scanning electron microscope (SEM) observation image of ceria abrasive grains of Example 2.

### DESCRIPTION OF THE INVENTION

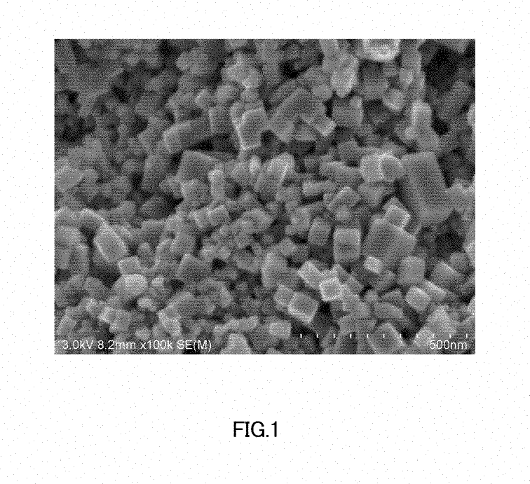

It is generally known that, when cerium oxide (hereinafter also referred to as “ceria”) is synthesized using a build-up process, {111}, {100}, and {110} crystal faces are exposed on cerium oxide surfaces. The inventors of the present disclosure conducted in-depth studies, and as a result, they discovered that it is possible to improve the polishing rate by using ceria abrasive grains in which {100} faces are exposed (see FIG. 1) in polishing, thereby achieving the present disclosure. In the present disclosure, the {100} faces correspond to {200} faces, which correspond to the peak around 33° detected in X-ray diffraction measurement of cerium oxide.

That is, the present disclosure relates to cerium oxide abrasive grains for use in an abrasive, in which at least 30% of the surface of each cerium oxide abrasive grain is {100} faces (the cerium oxide abrasive grains are also hereinafter referred to as “the ceria abrasive grains according to the present disclosure”). The ceria abrasive grains according to the present disclosure can improve the polishing rate.

Cerium Oxide (Ceria) Abrasive Grains

The shape of the ceria abrasive grains according to the present disclosure is spherical or polyhedral, for example. From the viewpoint of improving the polishing rate, the shape of the ceria abrasive grains is preferably a hexahedron surrounded by squares, more preferably a parallelepiped, still more preferably a cuboid, and yet more preferably a cube.

From the viewpoint of improving the polishing rate, the surfaces of the ceria abrasive grains to come into contact with a substrate to be polished during polishing are preferably {100} faces, and the larger the amount of the {100} faces exposed on the surface of the ceria abrasive grain, the better. From the viewpoint of improving the polishing rate, in the ceria abrasive grains according to the present disclosure, the amount of the {100} faces exposed on the surface of each cerium oxide abrasive grain is at least 30%, preferably at least 45%, more preferably at least 60%, and still more preferably 100%. As the amount of the exposed {100} faces increases, the shape of the ceria abrasive grains approximates a hexahedron surrounded by squares, and the shape of the ceria abrasive grains when the exposed amount is 100% is a hexahedron surrounded by squares (see FIG. 1). In the present disclosure, the amount of the exposed {100} faces can be calculated through image analysis by SEM observation or the like, for example. Specifically, the exposed amount can be determined by observing one grain or a plurality of randomly selected grains using SEM or the like and calculating, regarding the one grain in the observation image, the proportion of the area of the square portions in the surface area or calculating, regarding each of the plurality of grains in the observation image, the proportion of the area of the square portions in the total surface area and calculating the average value of the thus-calculated proportions. More specifically, the exposed amount can be determined by using the method described in the examples. In the present disclosure, square portions in the grains in an image obtained by SEM observation or the like can be regarded as {100} faces.

As a method for controlling the amount of the exposed {100} faces, it is possible to employ the method described in J. Phys. Chem. B 2005, 109, pp. 24380-24385 or the method described in Crystal Growth & Design, Vol. 9, No. 12, pp. 5297-5303, 2009, for example. Examples of the method include: generating cerium oxide having a specific crystal shape through hydrothermal treatment performed under high-concentration and highly alkaline conditions: and generating cerium oxide by crystallizing a hydroxide generated beforehand from a raw material of cerium and an alkali under supercritical conditions (e.g., 400° C. and 38 MPa). By adding at least one compound selected from monocarboxylic acids such as decanoic acid and dodecanoic acid, dicarboxylic acids such as adipic acid and pimelic acid, carboxylic acid polymers such as polyacrylic acids, and phosphate compounds such as trisodium phosphate as appropriate during the crystal growth, the compound(s) is adsorbed on a specific crystal plane. Accordingly, it is considered that, in the crystal shape that is ultimately obtained, faces to which the compound(s) is adsorbed are selectively protected and thus remain, and the crystal shape can be controlled.

The average primary particle size of the ceria abrasive grains according to the present disclosure is preferably 10 nm or more, more preferably 20 nm or more, and still more preferably 30 nm or more from the viewpoint of improving the polishing rate, and is preferably 150 nm or less, more preferably 130 nm or less, and still more preferably 100 nm or less from the viewpoint of reducing scratches. More specifically, the average primary particle size of the ceria abrasive grains according to the present disclosure is preferably not less than 10 nm and not more than 150 nm, more preferably not less than 10 nm and not more than 130 nm, still more preferably not less than 10 nm and not more than 100 nm, yet more preferably not less than 20 nm and not more than 100 nm, and even more preferably not less than 30 nm and not more than 100 nm. In the present disclosure, the average primary particle size of the ceria abrasive grains can be measured by using the method described in the examples.

The ceria abrasive grains according to the present disclosure are preferably formed of colloidal ceria from the viewpoint of improving the polishing rate. The colloidal ceria can be obtained through the build-up process described in JP 2010-505735 A, for example.

The ceria abrasive grains according to the present disclosure may be ceria particles composed of ceria alone, or may be composite oxide particles with some of the cerium atoms (Ce) in the cerium oxide abrasive grains being substituted with other atoms. The other atoms may be zirconium atoms (Zr), for example. That is, the ceria abrasive grains according to the present disclosure may be, for example, composite oxide particles with some of the Ce in the ceria abrasive grains being substituted with Zr, composite oxide particles containing Ce and Zr, or composite oxide particles in which Zr is dissolved in ceria (CeO₂) crystal lattices so as to form a solid solution. When the ceria abrasive grains according to the present disclosure are the composite oxide particles with some of the Ce in the ceria abrasive grains being substituted with Zr, from the viewpoint of improving the polishing rate, the content (mol %) of Zr in the ceria abrasive grains is preferably 15 mol % or more and more preferably 20 mol % or more, and also is preferably 35 mol % or less and more preferably 30 mol % or less, with respect to the total amount of Ce and Zr (100 mol %). More specifically, the content (mol %) of Zr in the ceria abrasive grains according to the present disclosure is preferably not less than 15 mol % and not more than 35 mol % and more preferably not less than 20 mol % and not more than 30 mol %, with respect to the total amount of Ce and Zr (100 mol %). As a method for producing the composite oxide particles, the method described in JP 2009-007543A can be employed, for example.

In one embodiment, the ceria abrasive grains according to the present disclosure can be used as polishing particles. Also, in another embodiment, the ceria abrasive grains according to the present disclosure can be used for polishing.

Polishing Liquid Composition

The present disclosure relates to a polishing liquid composition containing the ceria abrasive grains according to the present disclosure and an aqueous medium (hereinafter, this polishing liquid composition is also referred to as “the polishing liquid composition according to the present disclosure”).

The content of the ceria abrasive grains in the polishing liquid composition according to the present disclosure is preferably 0.05 mass % or more, more preferably 0.1 mass % or more, and still more preferably 0.2 mass % or more from the viewpoint of improving the polishing rate, and also is preferably 5 mass % or less, more preferably 2.5 mass % or less, and still more preferably 1 mass % or less from the same viewpoint. More specifically, the content of the ceria abrasive grains in the polishing liquid composition according to the present disclosure is preferably not less than 0.05 mass % and not more than 5 mass %, more preferably not less than 0.1 mass % and not more than 2.5 mass %, and still more preferably not less than 0.2 mass % and not more than 1 mass %.

The aqueous medium contained in the polishing liquid composition according to the present disclosure may be, for example, water, a mixture of water and a water-soluble solvent, or the like. Examples of the water-soluble solvent include lower alcohols such as methanol, ethanol, and isopropanol, and from the viewpoint of safety in the polishing step, ethanol is preferable. From the viewpoint of improving the quality of semiconductor substrates, the aqueous medium is preferably water such as ion-exchange water, distilled water, or ultrapure water. The content of the aqueous medium in the polishing liquid composition according to the present disclosure with the total mass of the ceria abrasive grains, optional components to be described below, and the aqueous medium being 100 mass % may be the remainder of the polishing liquid composition excluding the ceria abrasive grains and the following optional components.

Optional Components From the viewpoint of improving the polishing rate, the polishing liquid composition of the present disclosure preferably contains, as a polishing aid, a compound having an anionic group (hereinafter also referred to simply as “compound A”).

Examples of the anionic group of the compound A include carboxylic acid groups, sulfonic acid groups, sulfuric ester groups, phosphoric ester groups, and phosphonic acid groups. These anionic groups may be in the form of neutralized salts. A counter ion when the anionic group is in the form of a salt may be a metal ion, an ammonium ion, an alkylammonium ion, or the like, and from the viewpoint of improving the quality of semiconductor substrates, the ammonium ion is preferable.

The compound A may be, for example, at least one selected from citric acid and anionic polymers. When the compound A is an anionic polymer, a specific example thereof is at least one selected from polyacrylic acids, polymethacrylic acids, polystyrene sulfonates, copolymers of a (meth)acrylic acid and a monomethoxypolyethyleneglycol mono(meth)acrylate, copolymers of a (meth)acrylate having an anionic group and a monomethoxypolyethyleneglycol mono(meth)acrylate, copolymers of an alkyl (meth)acrylate, a (meth)acrylic acid, and a monomethoxypolyethyleneglycol mono(meth)acrylate, alkali metal salts thereof, and ammonium salts thereof. From the viewpoint of improving the quality of semiconductor substrates, the anionic polymer is preferably at least one selected from polyacrylic acids and ammonium salts thereof.

From the viewpoint of improving the polishing rate, the weight-average molecular weight of the compound A is preferably 1,000 or more, more preferably 10,000 or more, and still more preferably 20,000 or more, and also is preferably 5,500,000 or less, more preferably 1,000,000 or less, and still more preferably 100,000 or less. More specifically, the weight-average molecular weight of the compound A is preferably not less than 1,000 and not more than 5,500,000, more preferably not less than 10,000 and not more than 1,000,000, and still more preferably not less than 20,000 and not more than 100,000.

In the present disclosure, the weight-average molecular weight of the compound A can be measured through gel permeation chromatography (GPC) under the following conditions using a liquid chromatograph (Hitachi, Ltd., L-6000 High Performance Liquid Chromatograph).

### <Measurement Conditions>

Detector: Shodex RI SE-61 differential refractive index detector

Column: G4000PWXL and G2500PWXL (both manufactured by Tosoh Corp.) connected in series were used.

Eluent: 20 μL of 0.2 M phosphate buffer solution/acetonitrile=90/10 (volume ratio) was used after adjusting the concentration thereof to 0.5 g/100 mL.

Column temperature: 40° C.

Flow rate: 1.0 mL/min

Standard polymer: monodispersed polyethylene glycol with a known molecular weight

The content of the compound A in the polishing liquid composition according to the present disclosure is preferably 0.01 parts by mass or more, more preferably 0.05 parts by mass or more, and still more preferably 0.1 parts by mass or more with respect to 100 parts by mass of the ceria abrasive grains from the viewpoint of improving the polishing rate, and also is preferably 100 parts by mass or less, more preferably 10 parts by mass or less, and still more preferably 1 part by mass or less with respect to 100 parts by mass of the ceria abrasive grains from the same viewpoint. More specifically, the content of the compound A in the polishing liquid composition according to the present disclosure is preferably not less than 0.01 parts by mass and not more than 100 parts by mass, more preferably not less than 0.05 parts by mass and not less than 10 parts by mass, and still more preferably not less than 0.1 parts by mass and not more than 1 part by mass with respect to 100 parts by mass of the ceria abrasive grains.

From the viewpoint of improving the polishing rate, the content of the compound A in the polishing liquid composition according to the present disclosure is preferably 0.001 mass % or more, more preferably 0.0015 mass % or more, and still more preferably 0.0025 mass % or more, and also is preferably 1 mass % or less, more preferably 0.8 mass % or less, and still more preferably 0.6 mass % or less. More specifically, the content of the compound A in the polishing liquid composition according to the present disclosure is preferably not less than 0.001 mass % and not more than 1 mass %, more preferably not less than 0.0015 mass % and not more than 0.8 mass %, and still more preferably not less than 0.0025 mass % and not more than 0.6 mass %.

The polishing liquid composition according to the present disclosure may contain one or more other optional components such as a pH adjuster and polishing aids other than the compound A to the extent that the effect of the present disclosure is not impaired. From the viewpoint of ensuring an improved polishing rate, the content of the other optional component(s) in the polishing liquid composition according to the present disclosure is preferably 0.001 mass % or more, more preferably 0.0025 mass % or more, and still more preferably 0.01 mass % or more, and also is preferably 1 mass % or less, more preferably 0.5 mass % or less, and still more preferably 0.1 mass % or less. More specifically, the content of the other optional component(s) in the polishing liquid composition according to the present disclosure is preferably not less than 0.001 mass % and not more than 1 mass %, still more preferably not less than 0.0025 mass % and not more than 0.5 mass %, and still more preferably not less than 0.01 mass % and not more than 0.1 mass %.

The pH adjuster may be an acidic compound or an alkaline compound, for example. Examples of the acidic compound include: inorganic acids such as hydrochloric acid, nitric acid, and sulfuric acid; and organic acids such as acetic acid, oxalic acid, citric acid, and malic acid. In particular, the acidic compound is preferably at least one selected from hydrochloric acid, nitric acid, and acetic acid and more preferably at least one selected from hydrochloric acid and acetic acid in terms of their versatility. Examples of the alkaline compound include: inorganic alkaline compounds such as ammonia and potassium hydroxides; and organic alkaline compounds such as alkylamines and alkanolamines. In particular, the alkaline compound is preferably at least one selected from ammonia and alkylamines and more preferably ammonia from the viewpoint of improving the quality of semiconductor substrates.

The polishing aid other than the compound A may be an anionic surfactant other than the compound A, a nonionic surfactant, or the like. Examples of the anionic surfactant other than the compound A include alkyl ether acetates, alkyl ether phosphates, and alkyl ether sulfates. Examples of the nonionic surfactant include: nonionic polymers such as polyacrylamide; polyoxyalkylene alkyl ethers; and polyoxyethylene distyrenated phenyl ethers.

The polishing liquid composition according to the present disclosure can be produced by a production method that includes the step of blending the ceria abrasive grains according to the present disclosure, an aqueous medium, and, when desired, the above-described compound A and other optional component(s) by a known method. For example, the polishing liquid composition according to the present disclosure may be a composition obtained by blending at least the ceria abrasive grains according to the present disclosure and an aqueous medium. The term “blending” as used in the present disclosure encompasses mixing the ceria abrasive grains according to the present disclosure, an aqueous medium, and when necessary, the above-described optional component(s) either simultaneously or sequentially. The mixing order is not particularly limited. The blending may be performed using a mixer such as a homomixer, a homogenizer, an ultrasonic disperser, or a wet ball mill, for example. The amounts of the respective components to be blended in the method for producing the polishing liquid composition according to the present disclosure may be the same as the above-described contents of the respective components in the polishing liquid composition according to the present disclosure.

The polishing liquid composition according to the present disclosure may be embodied as a so-called one-pack type polishing liquid composition that is available on the market in the state where all the components are mixed beforehand, or as a so-called two-pack type polishing liquid composition adapted such that the components thereof are mixed when the polishing liquid composition is used.

From the viewpoint of improving the polishing rate, the pH of the polishing liquid composition according to the present disclosure is preferably 3.5 or more, more preferably 4 or more, and still more preferably 4.5 or more, and also is preferably 10 or less, more preferably 9 or less, and still more preferably 8 or less. More specifically, the pH of the polishing liquid composition according to the present disclosure is not less than 3.5 and not more than 10, more preferably not less than 4 and not more than 9, and still more preferably not less than 4.5 and not more than 8. In the present disclosure, the pH of the polishing liquid composition is the pH value at 25 C°, measured using a pH meter. In the present disclosure, the pH of the polishing liquid composition can be measured specifically by using the method described in the examples.

In the present disclosure, “the contents of the respective components in the polishing liquid composition” refer to the contents of the above-described respective components when the polishing liquid composition is used for polishing, i.e., at the start of using the polishing liquid composition for polishing. The polishing liquid composition according to the present disclosure may be stored and supplied in the state of being concentrated to the extent that the stability of the polishing liquid composition is not impaired. This is preferable because the production and transportation costs can be reduced. This concentrate can be used in the polishing step after being diluted as appropriate with the above-described aqueous medium, when necessary. The dilution ratio is preferably 5-fold to 100-fold.

An object to be polished with the polishing liquid composition according to the present disclosure may be a silicon oxide film, for example. Accordingly, the polishing liquid composition according to the present disclosure can be used in steps that require polishing of a silicon oxide film, and can be used suitably in, for example, polishing of a silicon oxide film performed in the step of forming an element isolation structure on a semiconductor substrate, polishing of a silicon oxide film performed in the step of forming an interlayer insulating film, polishing of a silicon oxide film performed in the step of forming embedded metal wiring, polishing of a silicon oxide film performed in the step of forming an embedded capacitor, or the like.

Polishing Liquid Kit

The present disclosure relates to a polishing liquid kit for producing a polishing liquid composition, including an abrasive grain dispersion, which is a dispersion containing the ceria abrasive grains according to the present disclosure, contained in a container. The polishing liquid kit according to the present disclosure can provide a polishing liquid kit with which a polishing liquid composition that can improve the polishing rate can be prepared.

One embodiment of the polishing liquid kit according to the present disclosure is, for example, a polishing liquid kit that includes a dispersion (first liquid) containing ceria abrasive grains according to the present disclosure and an aqueous medium, and a solution (second liquid) containing an additive(s) and an aqueous medium in a state where the first liquid and the second liquid are not mixed together (two-pack type polishing liquid composition). The first liquid and the second liquid are mixed together when the polishing liquid composition is used, and the thus-obtained mixture is diluted with an aqueous medium, when necessary. Examples of the additive include polishing aids, acids, oxidizing agents, heterocyclic aromatic compounds, aliphatic amine compounds, alicyclic amine compounds, and sugar compounds. The first liquid and the second liquid may each contain a pH adjuster, a thickening agent, a dispersant, a rust-preventive agent, a basic substance, a polishing rate improver, and/or the like, when necessary. The first liquid and the second liquid may be mixed together before they are supplied to a surface of an object to be polished, or they may be separately supplied to the surface of the substrate to be polished and then mixed together on the surface.

Method for Producing Semiconductor Substrate

The present disclosure relates to a method for producing a semiconductor substrate, including the step of polishing a substrate to be polished using the polishing liquid composition according to the present disclosure (hereinafter, this step is also referred to as “the polishing step using the polishing liquid composition according to the present disclosure”) (hereinafter, this method is also referred to as “the semiconductor substrate production method according to the present disclosure”). According to the semiconductor substrate production method according to the present disclosure, the polishing rate in the polishing step can be improved by using the polishing liquid composition of the present disclosure. Therefore, the semiconductor substrate production method according to the present disclosure can exhibit an effect that the semiconductor substrate can be produced efficiently.

In one or more embodiments, the substrate to be polished may be a substrate that has a film to be polished on its surface, a substrate that has a film to be polished formed on its surface, or a substrate that has a polishing stopper film disposed under a film to be polished so as to be in contact with the film to be polished, or the like. The film to be polished may be a silicon oxide film, for example. The polishing stopper film may be a silicon nitride film or a polysilicon film. The substrate may be a semiconductor substrate, for example. The semiconductor substrate may be a silicon substrate, for example. Also, the semiconductor substrate may be a substrate formed of an elemental semiconductor such as Si or Ge, a compound semiconductor such as GaAs, InP, or CdS, or a mixed crystal semiconductor such as InGaAs or HgCdTe.

A specific example of the semiconductor substrate production method according to the present disclosure is as follows. First, a silicon substrate is exposed to oxygen in an oxidation furnace to cause a silicon dioxide layer to grow on its surface. Then, on this silicon dioxide layer, a polishing stopper layer such as a silicon nitride (Si₃N₄) film or a polysilicon film is formed by using a chemical vapor deposition method (CVD method), for example. Next, a trench is formed using a photolithography technique on the substrate that includes the silicon substrate and the silicon nitride film disposed on one of the principal surfaces of the silicon substrate, e.g., on the substrate that has the polishing stopper layer formed on the silicon dioxide layer of the silicon substrate. Subsequently, a silicon oxide (SiO₂) film, which is a film to be polished for trench embedding, is formed using a CVD method using silane gas and oxygen gas, for example. Thus, the substrate to be polished in which the polishing stopper film is covered with the film to be polished (silicon oxide film) is obtained. As a result of forming the silicon oxide film, the trench is filled with silicon oxide of the silicon oxide film, and the surface of the polishing stopper film opposite to the surface on the silicon substrate side is covered with the silicon oxide film. The surface of the thus-formed silicon oxide film opposite to the surface on the silicon substrate side has levels formed corresponding to irregularities on the lower layer. Next, the silicon oxide film is polished by using a CMP method at least until the surface of the polishing stopper film opposite to the surface on the silicon substrate side is exposed, more preferably until the surface of the silicon oxide film is flush with the surface of the polishing stopper film. The polishing liquid composition according to the present disclosure can be used in the polishing step using this CMP method.

In the polishing according to the CMP method, irregularities on the surface of a substrate to be polished are planarized by, in the state where the surface of the substrate is in contact with a polishing pad, relatively moving the substrate to be polished and the polishing pad while supplying the polishing liquid composition according to the present disclosure to the contact portion. In the semiconductor substrate production method according to the present disclosure, another insulating film may be formed between the silicon dioxide layer and the polishing stopper film on the silicon substrate, or another insulating film may be formed between the film to be polished (e.g., silicon oxide film) and the polishing stopper film (e.g., the silicon nitride film).

In the polishing step using the polishing liquid composition according to the present disclosure, the number of revolutions of the polishing pad can be set to, for example, 30 to 200 r/min, the number of revolutions of the substrate to be polished can be set to, for example, 30 to 200 r/min, the polishing load of a polishing apparatus equipped with the polishing pad can be set to, for example, 20 to 500 g weight/cm², and the feed rate of the polishing liquid composition can be set to, for example, 10 to 500 mL/min or less. When the polishing liquid composition is a two-pack type polishing liquid composition, by adjusting the feed rate (or the feed amount) of each of the first liquid and the second liquid, it is possible to adjust the polishing rate of each of the film to be polished and the polishing stopper film and the ratio between the polishing rate of the film to be polished and the polishing rate of the polishing stopper film (polishing selectivity).

In the polishing step using the polishing liquid composition according to the present disclosure, the polishing rate of the film to be polished (e.g., silicon oxide film) is preferably 800 Å/min or more, more preferably 2,000 Å/min or more, and still more preferably 3,000 Å/min or more from the viewpoint of improving the productivity.

In the polishing step using the polishing liquid composition according to the present disclosure, the polishing rate of the polishing stopper film (e.g., silicon nitride film) is preferably 500 Å/min or less, more preferably 300 Å/min or less, and still more preferably 150 Å/min or less from the viewpoint of improving the polishing selectivity and shortening the polishing time.

In the polishing step using the polishing liquid composition according to the present disclosure, the polishing rate ratio (the polishing rate of the film to be polished/the polishing rate of the polishing stopper film) is preferably 5 or more, more preferably 10 or more, still more preferably 20 or more, and yet more preferably 40 or more from the viewpoint of shortening the polishing time. The polishing selectivity in the present disclosure can be evaluated using the ratio of the polishing rate of the film to be polished to the polishing rate of the polishing stopper film (the polishing rate of the film to be polished/the polishing rate of the polishing stopper film), and high polishing selectivity means that the polishing rate ratio is large.

Polishing Method

The present disclosure relates to a method for polishing a substrate, including the step of polishing a substrate to be polished (polishing step) using the polishing liquid composition according to the present disclosure (hereinafter, this method is also referred to as “the polishing method according to the present disclosure”), and preferably relates to a method for polishing a substrate for use in production of a semiconductor substrate. By using the polishing method according to the present disclosure, the polishing rate in the polishing step can be improved. Therefore, the polishing method according to the present disclosure can exhibit an effect that the semiconductor substrate can be efficiently produced. In one or more embodiments, the polishing step in the polishing method according to the present disclosure is a step of polishing a surface of a substrate to be polished by, in the state where the surface of the substrate is in contact with a polishing pad, relatively moving the substrate and/or the polishing pad while supplying the polishing liquid composition according to the present disclosure between the substrate and the polishing pad. A specific polishing method and polishing conditions may be the same as those described above regarding the semiconductor substrate production method according to the present disclosure.

Method for Producing Semiconductor Device

One aspect of the present disclosure relates to a method for producing a semiconductor device, including the step of polishing a substrate to be polished (polishing step) using the polishing liquid composition according to the present disclosure (hereinafter, this method is also referred to as “the semiconductor device production method according to the present disclosure”). In one or more embodiments, the polishing step in the semiconductor device production method according to the present disclosure is a polishing step to be performed in at least one step selected from the step of forming an element isolation structure, the step of forming an interlayer insulating film, the step of forming embedded metal wiring, and the step of forming an embedded capacitor. The semiconductor device may be, for example, a memory IC (Integrated Circuit), a logic IC, a system LSI (Large-Scale Integration), or the like.

The semiconductor device production method according to the present disclosure can exhibit an effect that a semiconductor substrate is efficiently obtained, and thus the productivity of a semiconductor device can be improved. A specific polishing method and polishing conditions in the polishing step may be the same as those described above regarding the semiconductor substrate production method according to the present disclosure.

The present disclosure further relates to the following composition and production methods.

<1> Ceria abrasive grains for use in an abrasive,

in which an amount of {100} faces exposed on a surface of each of the ceria abrasive grains is at least 30%.

<2> The ceria abrasive grains according to <1>,

in which the amount of the {100} faces exposed on the surface of each of the ceria abrasive grains is at least 30%, preferably at least 45%, more preferably at least 60%, and still more preferably 100%.

<3> The ceria abrasive grains according to <1> or <2>,

in which an average primary particle size of the ceria abrasive grains is preferably 10 nm or more, more preferably 20 nm or more, and still more preferably 30 nm or more.

<4> The ceria abrasive grains according to any one of <1> to <3>,

in which an average primary particle size of the ceria abrasive grains is preferably 150 nm or less, more preferably 130 nm or less, and still more preferably 100 nm or less.

<5> The ceria abrasive grains according to any one of <1> to <4>,

in which the average primary particle size of the ceria abrasive grains is not less than 10 nm and not more than 150 nm.

<6> The ceria abrasive grains according to any one of <1> to <5>,

in which the ceria abrasive grains are composite oxide particles with some cerium atoms (Ce) in the ceria abrasive grains being substituted with zirconium atoms (Zr).

<7> The ceria abrasive grains according to <6>,

in which the content of Zr in the ceria abrasive grains is preferably 15 mol % or more and more preferably 20 mol % or more with respect to the total amount of Ce and Zr (100 mol %).

<8> The ceria abrasive grains according to <6> or <7>,

in which the content of Zr in the ceria abrasive grains is preferably 35 mol % or less and more preferably 30 mol % or less with respect to the total amount of Ce and Zr (100 mol %).

<9> Use of the ceria abrasive grains according to any one of <1> to <8> as polishing particles.
<10> Use of the ceria abrasive grains according to any one of <1> to <8> for polishing.
<11> A polishing liquid composition including:

the ceria abrasive grains according to any one of <1> to <8>; and

an aqueous medium.

<12> The polishing liquid composition according to <11>,

in which the content of the ceria abrasive grains is preferably 0.05 mass % or more, more preferably 0.1 mass % or more, and still more preferably 0.2 mass % or more.

<13> The polishing liquid composition according to <11> or <12>,

in which the content of the ceria abrasive grains is preferably 5 mass % or less, more preferably 2.5 mass % or less, and still more preferably 1 mass % or less.

<14> The polishing liquid composition according to any one of <11> to <13>,

in which the content of the ceria abrasive grains is not less than 0.05 mass % and not more than 5 mass %.

<15> The polishing liquid composition according to any one of <11> to <14>, further including a compound A having an anionic group.
<16> The polishing liquid composition according to <15>,

in which the weight-average molecular weight of the compound A is preferably 1,000 or more, more preferably 10,000 or more, and still more preferably 20,000 or more.

<17> The polishing liquid composition according to <15> or <16>,

in which the weight-average molecular weight of the compound A is preferably 5,500,000 or less, more preferably 1,000,000 or less, and still more preferably 100,000 or less.

<18> The polishing liquid composition according to any one of <15> to <17>,

in which the content of the compound A is preferably 0.01 parts by mass or more, more preferably 0.05 parts by mass or more, and still more preferably 0.1 parts by mass with respect to 100 parts by mass of the ceria abrasive grains.

<19> The polishing liquid composition according to any one of <15> to <18>,

in which the content of the compound A is preferably 100 parts by mass or less, more preferably 10 parts by mass or less, and still more preferably 1 parts by mass or less with respect to 100 parts by mass of the ceria abrasive grains.

<20> The polishing liquid composition according to any one of <15> to <19>,

in which the content of the compound A in the polishing liquid composition is preferably 0.001 mass % or more, more preferably 0.0015 mass % or more, and still more preferably 0.0025 mass % or more.

<21> The polishing liquid composition according to any one of <15> to <20>,

in which the content of the compound A in the polishing liquid composition is preferably 1 mass % or less, more preferably 0.8 mass % or less, and still more preferably 0.6 mass % or less.

<22> The polishing liquid composition according to any one of <11> to <21>, further including at least one other optional component selected from a pH adjuster and polishing aids other than the compound A.
<23> The polishing liquid composition according to <22>,

in which the content of the other optional component in the polishing liquid composition is preferably 0.001 mass % or more, more preferably 0.0025 mass % or more, and still more preferably 0.01 mass % or more.

<24> The polishing liquid composition according to <22> or <23>,

in which the content of the other optional component in the polishing liquid composition is preferably 1 mass % or less, more preferably 0.5 mass % or less, and still more preferably 0.1 mass % or less.

<25> The polishing liquid composition according to any one of <11> or <24>,

in which the pH of the polishing liquid composition is preferably 3.5 or more, more preferably 4 or more, and still more preferably 4.5 or more.

<26> The polishing liquid composition according to any one of <11> or <25>,

in which the pH of the polishing liquid composition is preferably 10 or less, more preferably 9 or less, and still more preferably 8 or less.

<27> The polishing liquid composition according to any one of <11> or <26>,

in which the polishing liquid composition is used for polishing a silicon oxide film.

<28> A polishing liquid kit for producing a polishing liquid composition, the polishing liquid kit including:

an abrasive grain dispersion contained in a container,

wherein the abrasive grain dispersion is a dispersion containing the ceria abrasive grains according to any one of <1> to <8>.

<29> A method for producing a semiconductor substrate, including the step of:

polishing a substrate to be polished using the polishing liquid composition according to any one of <11> to <27>.

<30> A method for polishing a substrate, including the step of:

polishing a substrate to be polished using the polishing liquid composition according to any one of <11> to <27>, which is preferably a method for polishing a substrate for use in production of a semiconductor substrate.

<31> The polishing method according to <30>,

in which the step of polishing the substrate to be polished is a step of polishing a surface of a substrate to be polished by, in a state where the surface of the substrate is in contact with a polishing pad, relatively moving the substrate and/or the polishing pad while supplying the polishing liquid composition according to any one of <11> to <27> between the substrate and the polishing pad.

<32> A method for producing a semiconductor device, including the step of:

polishing a substrate to be polished using the polishing liquid composition according to any one of <11> to <27>.

<33> The method according to <32>,

in which the step of polishing the substrate to be polished is a polishing step to be performed in at least one step selected from the step of forming an element isolation structure, the step of forming an interlayer insulating film, the step of forming embedded metal wiring, and the step of forming an embedded capacitor.

### Examples

Hereinafter, the present disclosure will be described in further detail by way of examples. However, these examples are merely illustrative, and the present disclosure is not limited to the following examples.

1. Measurement of Respective Parameters

### pH of Polishing Liquid Composition

The pH value of a polishing liquid composition at 25° C. was measured using a pH meter (DKK-TOA CORPORATION, “HM-30G”). The pH value was read from a pH meter one minute after dipping the electrode of the pH meter into the polishing liquid composition.

Average Primary Particle Size of Ceria Abrasive Grains

The average primary particle size (nm) of ceria abrasive grains was calculated from an image obtained through transmission electron microscope (TEM) observation.

Specifically, the ceria abrasive grains were dispersed in ion-exchange water such that the concentration of the ceria abrasive grains was 0.01 mass % to obtain a dispersion slurry. The dispersion slurry was dropped onto a grid, air-dried, and then subjected to TEM observation. Out of the abrasive grains present in the obtained image, the diameters of circumscribed circles of 100 abrasive grains were measured, and the average value thereof was determined as a primary particle size.

Analysis of Crystal Face Orientation of Ceria

Crystal face orientation of ceria was analyzed using a transmission electron microscope (TEM). Specifically, from the electron diffraction image provided by the TEM, it was confirmed that the crystal structure of ceria was a fluorite type structure, and the crystal lattice spacing (interplanar spacing) was identified. Next, the crystal lattice image provided by the TEM was enhanced by applying a Fourier filter, and a crystal face orientation map was prepared based on the relationship between the obtained crystal lattice image and crystal axis orientation and the crystal lattice spacing (interplanar spacing) thereof. In the thus-prepared crystal face orientation map, square portions of the grains correspond to the {100} faces.

Amount of Exposed {100} Faces

The amount of {100} faces exposed on ceria abrasive grains was measured in the following manner. The ceria abrasive grains were dispersed in ion-exchange water such that the concentration of the ceria abrasive grains was 0.01 mass % to obtain a dispersion slurry. The dispersion slurry was dropped onto a grid and air-dried. Thereafter, randomly selected 100 grains were observed with a scanning electron microscope (SEM). In the obtained image, the square portions on the surfaces of the grains were regarded as {100} faces, and regarding each of the 100 grains in the SEM observation image, the proportion of the area of the square portions to the total surface area was calculated. The average value of the thus-obtained proportions was calculated as the amount of the exposed {100} faces.

The shape of each grain in the SEM observation image is a shape observed from only one direction. In this measurement, the exposed amount was calculated based on the assumption that the shape of the grain was symmetrical, i.e., that the shape (front surface shape) of the grain observed with the SEM from only one direction is the same as the shape (rear surface shape) of the grain observed from a direction opposite to the above-described one direction.

2. Method for Producing Ceria Abrasive Grains and Details Thereof

### <Production Example of Ceria Abrasive Grains of Example 1>

As a raw material of cerium, 0.868 g (0.002 mol) of cerium(III) nitrate hexahydrate was dissolved in 5 mL of ion-exchange water. Next, 8.5 g (0.2125 mol) of sodium hydroxide was dissolved in 35 mL of ion-exchange water (about 6 mol/L). The above-described cerium nitrate aqueous solution was added to this sodium hydroxide aqueous solution while being stirred, and the stirring was continued for at least 30 minutes to form a precipitate. To the slurry containing the precipitate, a crystal control agent (adipic acid or pimelic acid) in an amount equivalent to the amount of the precipitate (0.002 mol) was added, and the resultant mixture was stirred for 30 minutes. Thereafter, the mixture was similarly transferred to a 50 mL Teflon® container. This Teflon® container was placed in a stainless steel reaction vessel (an autoclave manufactured by SAN-AI Kagaku Co. Ltd.), and the reaction vessel was sealed. The stainless steel container with the Teflon® container contained therein was placed in a fan dryer, and was subjected to hydrothermal treatment at 180° C. for 24 hours. After completion of the hydrothermal treatment, the mixture was cooled to room temperature. The precipitate was sufficiently washed with ion-exchange water, and then dried with a fan dryer at 100° C. As a result, a powder (ceria abrasive grains of Example 1) was obtained.

X-ray diffraction confirmed that the thus-obtained powder was cerium oxide. Further, a small amount of the powder was dispersed in ion-exchange water, and the obtained dispersion was subjected to TEM observation and SEM observation. As a result, it was confirmed that the thus-obtained powder was cerium oxide in a cubo-octahedral shape.

The crystal control agent (adipic acid or pimelic acid) was adsorbed on the surfaces of the ceria abrasive grains of Example 1. Thus, before using the ceria abrasive grains of Example 1 for preparation of a polishing liquid composition to be described below, the ceria abrasive grains of Example 1 were further heat-treated in an electric furnace at 250° C. for 1 hour to remove the crystal control agent adsorbed on the surfaces of the abrasive grains. This heat treatment did not cause any change in the shape of the ceria abrasive grains.

<Production Example of Ceria Abrasive Grains of Example 2>

As a raw material of cerium, 0.868 g (0.002 mol) of cerium(III) nitrate hexahydrate was dissolved in 5 mL of ion-exchange water. Next, 8.5 g (0.2125 mol) of sodium hydroxide was dissolved in 35 mL of ion-exchange water (about 6 mol/L). The above-described cerium nitrate aqueous solution was added to this sodium hydroxide aqueous solution while being stirred, and the stirring was continued for at least 30 minutes to form a precipitate. Thereafter, the slurry containing the precipitate was transferred to a 50 mL Teflon® container. This Teflon® container was placed in a stainless steel reaction vessel (an autoclave manufactured by SAN-AI Kagaku Co. Ltd.), and the reaction vessel was sealed. The stainless steel container with the Teflon® container contained therein was placed in a fan dryer, and was subjected to a hydrothermal treatment at 180° C. for 24 hours. After completion of the hydrothermal treatment, the mixture was cooled to room temperature. The precipitate was sufficiently washed with ion-exchange water, and then dried with a fan dryer at 100° C. As a result, a powder (ceria abrasive grains of Example 2) was obtained.

X-ray diffraction confirmed that the thus-obtained powder was cerium oxide. Further, a small amount of the powder was dispersed in ion-exchange water, and the obtained dispersion was subjected to TEM observation and SEM observation. As a result, it was confirmed that the thus-obtained powder was cerium oxide in a hexahedron shape surrounded by squares with only {100} faces being exposed. FIG. 1 is a SEM observation image of the ceria abrasive grains according to Example 2. By performing crystal structure analysis, it was found that the exposed crystal faces were all {100} faces.

<Production Example of Ceria Abrasive Grains of Example 3>

Ceria abrasive grains of Example 3 were obtained by performing the same operations as in Example 2, except that the hydrothermal treatment at 180° C. was performed for 12 hours.

<Production Example of Ceria Abrasive Grains of Example 4>

Ceria abrasive grains of Example 4 were obtained by performing the same operations as in Example 1, except that the amount of the crystal control agent (adipic acid or pimelic acid) to be added was set to ½ mol (0.001 mol) of the amount of the formed precipitate.

<Production Example of Ceria Abrasive Grains of Example 5>

Ceria abrasive grains of Example 5 were obtained by performing the same operations as in Example 1, except that the amount of the crystal control agent (adipic acid or pimelic acid) to be added was set to 1/10 mol (0.0002 mol) of the amount of the formed precipitate.

<Production Example of Ceria Abrasive Grains of Example 6>

Ceria abrasive grains of Example 6 were obtained by performing the same operations as in Example 2, except that, as the raw materials of cerium, 0.651 g (0.0015 mol) of cerium(III) nitrate hexahydrate and 0.134 g (0.0005 mol) of zirconium oxynitrate dihydrate were used.

The thus-obtained dry powder of the ceria abrasive grains of Example 6 was analyzed using X-ray diffraction. As a result, no crystal peak other than that of ceria was observed, and further, the observed peak was shifted to a higher angle side than the theoretical peak of ceria. To 0.1 g of the obtained powder, 10 mL of nitric acid was added, and five to six drops of a hydrogen peroxide solution was added thereto with a dropper. Ultrapure water was further added thereto such that the total amount of the mixture was about 30 mL. A rotor was placed in the mixture, and a watch glass made of Teflon® was placed thereon as a lid. Further, to the mixture placed on a stirrer equipped with a heater, hydrogen peroxide was added drop by drop, and dissolved while being heated until the mixture became transparent. Thereafter, the mixture was left to cool down, and then transferred to a 100 mL plastic volumetric flask. A quartz beaker was washed with ultrapure water, and the mixture in the volumetric flask was further transferred to the quartz beaker. This washing operation was repeated a total of three times, and the mixture brought up to volume with the ultrapure water. Using this as a sample solution, elemental analysis with ICP was performed. As a result, it was found that the ratio between Ce and Zr (Ce Zr) was 74.5:25.5 (molar ratio).

<Production Example of Ceria Abrasive Grains of Example 7>

Ceria abrasive grains of Example 7 were obtained by performing the same operations as in Example 2, except that, as raw materials of cerium, 0.608 g (0.0014 mol) of cerium(III) nitrate hexahydrate and 0.161 g (0.0006 mol) of zirconium oxynitrate dihydrate were used.

The thus-obtained dry powder of the ceria abrasive grains of Example 7 was analyzed using X-ray diffraction. As a result, no crystal peak other than that of ceria was observed, and further, the observed peak was shifted to a higher angle side than the theoretical peak of ceria. Also, elemental analysis was performed in the same manner as in Example 6. As a result, it was found that the ratio between Ce and Zr (Ce:Zr) was 69.7:30.3 (molar ratio).

<Production Example of Ceria Abrasive Grains of Example 8>

Ceria abrasive grains of Example 8 were obtained by performing the same operations as in Example 2, except that the hydrothermal treatment was performed for 120 hours.

<Ceria Abrasive Grains of Comparative Examples 1 to 3>

As ceria abrasive grains of Comparative Example 1, pulverized ceria (Showa Denko K.K., “GPL-C1010”) was used. As ceria abrasive grains of Comparative Example 2, “HC60” manufactured by Anan Kasei Co. Ltd. was used. As ceria abrasive grains of Comparative Example 3, “Nano Ceria” manufactured by Adcon was used.

3. Preparation of Polishing Liquid Compositions (Examples 1 to 8 and Comparative Examples 1 to 3)

The ceria abrasive grains of Examples 1 to 8 and Comparative Example 1 to 3 were each mixed with an aqueous medium (ultrapure water), and a pH adjuster was added to the resultant mixtures, when necessary. As a result, polishing liquid compositions of Examples 1 to 8 and Comparative Examples 1 to 3, each having a pH of 4.5 at 25° C., were obtained. The pH of each of the polishing liquid compositions was adjusted using ammonia or hydrochloric acid. The contents of the respective components in the respective polishing liquid compositions are shown in Table 1.

4. Evaluation of Polishing Liquid Compositions (Examples 1 to 8 and Comparative Examples 1 to 3)

### Production of Test Piece

A silicon oxide film with a thickness of 2000 nm was formed on one surface of a silicon wafer using a TEOS-plasma CVD method. A 40 mm×40 mm square piece was cut out therefrom to obtain a test piece of the silicon oxide film.

Measurement of Polishing Rate of Silicon Oxide Film (Film to be Polished)

As a polishing apparatus, “TR15M-TRK1” (Techno Rise Corporation) equipped with a platen having a diameter of 380 mm was used. As a polishing pad, a rigid urethane pad “IC-1000/Suba400” manufactured by Nitta Haas Incorporated was used. The polishing pad was attached to the platen of the polishing apparatus. The test piece was set in a holder, and the holder was placed on the polishing pad such that the surface of the test piece on which the silicon oxide film had been formed faced downward (such that the oxide film faced the polishing pad). Furthermore, a weight was placed on the holder such that a load of 300 g weight/cm² was applied to the test piece. The test piece of the silicon oxide film was polished by rotating both the platen and the holder in the same rotation direction at 90 r/min for one minute while dropping the polishing liquid composition at a rate of 50 mL/min onto the center of the platen to which the polishing pad was attached. After the polishing, the test piece of the silicon oxide film was washed with ultrapure water, dried, and subjected to measurement using an optical interference type film thickness measuring instrument to be described below.

The thicknesses of the silicon oxide film before and after the polishing were measured using the optical interference type film thickness measuring instrument (“Lambda Ace VM-1000” manufactured by Dainippon Screen Mfg. Co., Ltd.). The polishing rate of the silicon oxide film was calculated using the following equation, and shown in Table 1 below.

Polishing rate of silicon oxide film (Å/min)=[Thickness of silicon oxide film before polishing (Å)−Thickness of silicon oxide film after polishing (Å)]/Polishing time (min)

TABLE 1

| | Polishing liquid composition (in use) | | | | | |
|---|---|---|---|---|---|---|
| | Ceria abrasive grains | | | | | |
| | | Amount | Zr | | | |
| | Average | of | content | | | |
| | primary | exposed | in ceria | | Aqueous | |
| | particle | {100} | abrasive | | medium | Polishing |
| | size | faces | grains | Content | Content | rate |
| | [nm] | [%] | [mol %] | [mass %] | [mass %] | [Å/min] |
| Ex. 1 | 55 | 45 | — | 0.5 | 99.5 | 867 |
| Ex. 2 | 47 | 100 | — | 0.5 | 99.5 | 3500 |
| Ex. 3 | 10 | 100 | — | 0.5 | 99.5 | 800 |
| Ex. 4 | 55 | 60 | — | 0.5 | 99.5 | 2740 |
| Ex. 5 | 58 | 75 | — | 0.5 | 99.5 | 3020 |
| Ex. 6 | 48 | 100 | 25 | 0.5 | 99.5 | 5250 |
| Ex. 7 | 45 | 100 | 30 | 0.5 | 99.5 | 4900 |
| Ex. 8 | 90 | 45 | — | 0.5 | 99.5 | 2000 |
| Comp. | 42 | 0 | — | 0.5 | 99.5 | 430 |
| Ex. 1 | | | | | | |
| Comp. | 60 | 25 | — | 0.5 | 99.5 | 510 |
| Ex. 2 | | | | | | |
| Comp. | 10 | 0 | — | 0.5 | 99.5 | 200 |
| Ex. 3 | | | | | | |

As can be seen in Table 1, the polishing rates achieved using the polishing liquid compositions of Examples 1 to 8, which contained the cerium oxide abrasive grains with the amount of the exposed {100} faces being at least 30%, were improved as compared with those achieved using the polishing liquid compositions of Comparative Examples 1 to 3.

### INDUSTRIAL APPLICABILITY

The polishing liquid composition according to the present disclosure is useful in a method for producing a high density or high integration semiconductor substrate.

1. Cerium oxide abrasive grains for use in an abrasive,
wherein an amount of {100} faces exposed on a surface of each of the cerium oxide abrasive grains is at least 30%.

2. The cerium oxide abrasive grains according to claim 1,
wherein an average primary particle size of the cerium oxide abrasive grains is not less than 10 nm and not more than 150 nm.

3. The cerium oxide abrasive grains according to claim 1,
wherein the cerium oxide abrasive grains are composite oxide particles with some cerium atoms in the cerium oxide abrasive grains being substituted with zirconium atoms.

4. (canceled)

5. (canceled)

6. A polishing liquid composition comprising:
the cerium oxide abrasive grains according to claim 1; and
an aqueous medium.

7. The polishing liquid composition according to claim 6,
wherein a content of the cerium oxide abrasive grains is not less than 0.05 mass % and not more than 5 mass %.

8. The polishing liquid composition according to claim 6,
wherein the polishing liquid composition is used for polishing a silicon oxide film.

9. A method for producing a semiconductor substrate, the method comprising the step of:
polishing a substrate to be polished using the polishing liquid composition according to claim 6.

10. A method for polishing a substrate, the method comprising the step of:
polishing a substrate to be polished using the polishing liquid composition according to claim 6.

11. A method for producing a semiconductor device, the method comprising the step of:
polishing a substrate to be polished using the polishing liquid composition according to claim 6.
